(19) United States
(12) Patent Application Publication
(10) Pub. No.: US 2018/0267715 A1
(43) Pub. Date: Sep. 20, 2018

(54) MEMORY SYSTEM, MEMORY CONTROL DEVICE, AND METHOD OF CONTROLLING MEMORY SYSTEM

(71) Applicant: Toshiba Memory Corporation, Minato-ku (JP)

(72) Inventors: Hiroki Matsudaira, Funabashi (JP); Norio Aoyama, Machida (JP); Ryoichi Kato, Kawasaki (JP); Taku Ooneda, Machida (JP); Takashi Hirao, Ota (JP); Aurelien Nam Phong Tran, Yokohama (JP); Hiroyuki Yamaguchi, Kawasaki (JP); Takuya Suzuki, Fujisawa (JP); Hajime Yamazaki, Kawasaki (JP)

(73) Assignee: Toshiba Memory Corporation, Minato-ku (JP)

(21) Appl. No.: 15/915,530

(22) Filed: Mar. 8, 2018

(30) Foreign Application Priority Data
Mar. 16, 2017 (JP) 2017-051382

(51) Int. Cl. G06F 3/06

(52) U.S. Cl. CPC G06F 3/0611; G06F 3/0608; G11C 16/0483; G06F 3/0658; G06F 3/0679; G06F 3/0652

(57) ABSTRACT

According to one embodiment, the memory system includes a nonvolatile memory including a plurality of blocks, and a controller circuit that controls execution of a data writing process and a garbage collection process. Each of the blocks is an unit of erasure. The data writing process includes a process of writing user data into the nonvolatile memory in accordance with a request from an external member. The garbage collection process includes a process of moving valid data in at least a first block into a second block among the blocks and invalidating the valid data in the first block to be erasable. Upon receiving a data write request from the external member, the controller circuit controls a length of a waiting time to be provided before or after the data writing process within a period from receiving the write request to returning a response to the external member.

### CROSS-REFERENCE TO RELATED APPLICATIONS

This application is based upon and claims the benefit of priority from Japanese Patent Application No. 2017-051382, filed on Mar. 16, 2017; the entire contents of which are incorporated herein by reference.

### FIELD

Embodiments described herein relate generally to a memory system, a memory control device, and a method of controlling a memory system.

### BACKGROUND

In memory systems using a NAND type flash memory (which will be referred to as “NAND memory”, hereinafter) as a storage medium, it is necessary to perform a garbage collection (compaction) process and thereby to prepare one or more free blocks without valid data written therein. In the garbage collection process, valid data in a certain block is organized and moved into another block. At this time, the data in the copy source block is invalidated.

A data writing process for writing data from a host and the garbage collection process use the same storage device, and thus these processes cannot be simultaneously executed. In consideration of this, the writing ratio between the data writing process and the garbage collection process is calculated in advance, and the data writing process and the garbage collection process are performed on the basis of this writing ratio. However, between cases when the data writing process is performed and when the garbage collection process is performed in parallel with the data writing process, the writing time of data from the host, which is called “latency”, has variations. Particularly, the latency takes the maximum value when the garbage collection process is performed. Thus, it is necessary to wait for a long time until the data writing process is completed when the garbage collection process is executed. As described above, in the conventional data writing process, the processing time is considerably different between a case without the latency and a case with the latency.

### BRIEF DESCRIPTION OF THE DRAWINGS

FIG. 1 is a block diagram illustrating a configuration example of a memory system according to a first embodiment;

FIG. 2 is a diagram for explaining functional parts achieved by CPUs on the basis of firmware;

FIG. 3 is a flowchart illustrating an example of a control method of the memory system according to the first embodiment;

FIGS. 4A and 4B are diagrams each schematically illustrating a manner of a writing process and a garbage collection process;

FIG. 5 is a block diagram illustrating a configuration example of a memory system according to a second embodiment;

FIG. 6 is a diagram illustrating a configuration example of a logical block;

FIG. 7 is a diagram schematically illustrating data to be stored in a logical block;

FIG. 8 is a diagram illustrating a configuration example of a route table;

FIG. 9 is a diagram schematically illustrating a configuration example of a RAM according to the second embodiment;

FIGS. 10A and 10B are flowcharts each illustrating an example of a sequence of a management information restoring process according to the second embodiment;

FIG. 11 is a diagram schematically illustrating a configuration example of a RAM according to a comparative example; and

FIGS. 12A and 12B are flowcharts each illustrating an example of a sequence of a management information restoring process according to the comparative example.

### DETAILED DESCRIPTION

According to one embodiment, the memory system includes a nonvolatile memory including a plurality of blocks in which data is written from an external member, and a controller circuit that controls execution of a data writing process and a garbage collection process. Each of the blocks is an unit of erasure. The data writing process includes a process of writing user data into the nonvolatile memory in accordance with a request from the external member. The garbage collection process includes a process of moving valid data in at least a first block into a second block among the blocks and invalidating the valid data in the first block to be erasable. Upon receiving a data write request from the external member, the controller circuit controls a length of a waiting time to be provided before or after the data writing process within a period from receiving the write request to returning a response to the external member.

Exemplary embodiments of a memory system, a memory control device, and a method of controlling a memory system will be explained below in detail with reference to the accompanying drawings. The present invention is not limited to following embodiments.

### First Embodiment

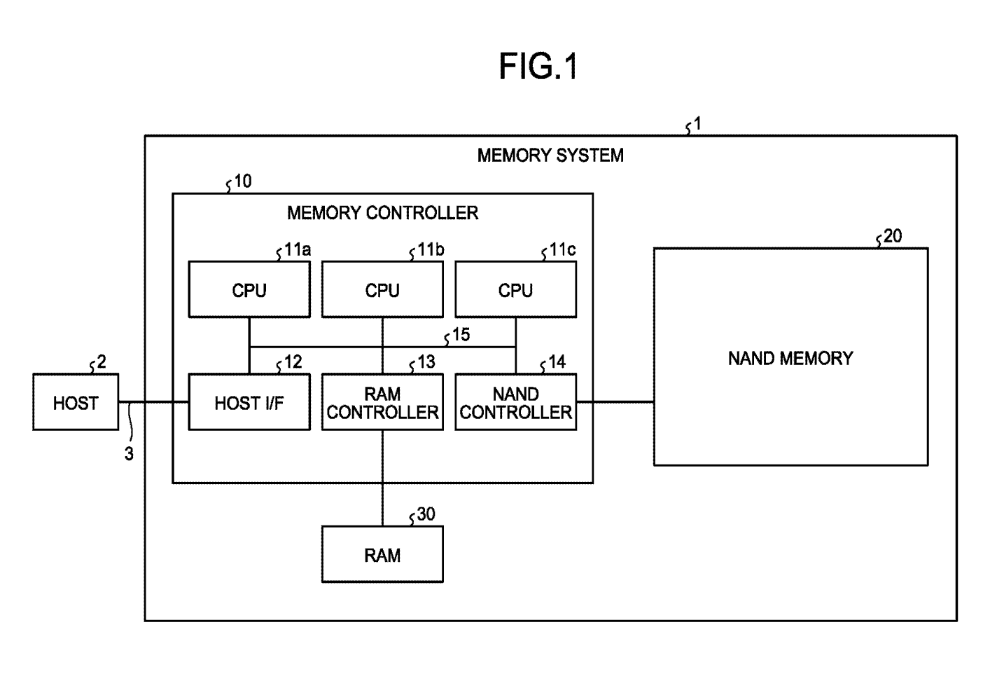

FIG. 1 is a block diagram illustrating a configuration example of a memory system according to a first embodiment. The memory system 1 is connected to a host 2 that is present outside, via a communication path 3. The host 2 may be a computer. For example, the computer includes a personal computer, portable computer, or portable communication equipment. The memory system 1 serves as an external storage device for the host 2. As the interface standard of the communication path 3, an arbitrary standard can be adopted. The host 2 can issue a write request and a read request to the memory system 1. Each of the write request and the read request includes logical address information designating an access destination. It should be noted that “external member” recited in “What is claimed is” means a computer, such as the host 2, connected via the communication path 3 other than the internal wiring lines connecting the components inside the memory system 1.

The memory system 1 includes a memory controller 10, a NAND memory 20 used as a storage, and a Random Access Memory (RAM) 30.

The NAND memory 20 is composed of one or more NAND chips including memory cell arrays. Each memory cell array is configured such that a plurality of memory cells are arrayed in a matrix shape. Each memory cell array is composed of a plurality of physical blocks arrayed, each being an erase unit. Each physical block includes a plurality of pages, each being an unit for reading and writing performed to each of the memory cell arrays.

In the NAND memory 20, erasing is performed in units of a physical block. Accordingly, under a state where first data is stored in the NAND memory 20, when second data is to be written from the host 2, of which a logical address is the same as that of the first data, the second data is written into an empty page and the first data is set as invalid-state data (which will be referred to as “invalid data”, hereinafter), instead of that the first data is erased. As writing is performed to the NAND memory 20 in this way, data stored in each physical block contains invalid data and valid-state data (which will be referred to as “valid data”, hereinafter) in a mixed state. Data being valid means that the data is in the latest state. There is a case where the NAND memory 20 stores a plurality of data written by designation of the same logical address. The latest state means a state of data last written by the host 2 among the plurality of data. In other words, valid data means data in the latest state with respect to a certain logical address. Data being invalid means that the data is not in the latest state any more because of post-writing. This means a state of data other than data last written by the host 2 among the plurality of data. Here, where there is a logical address that has been designated only once, data written by designation of this logical address is in the latest state. Further, whether data in a physical block is valid data or invalid data may be managed by using a bit map or flag, or may be written in a log to be added when the data is written into the NAND memory 20.

The NAND memory 20 stores user data and management information. The user data is data written in accordance with an instruction from the host 2. The management information is information for the memory controller 10 to perform access to the NAND memory 20, and contains translation information, free block information, and so forth. The translation information is information for translating logical addresses into physical addresses. It is assumed that, under a state where first data is written in a first physical address on the NAND memory 20 with respect to a certain logical address, second data is to be written into a second physical address on the NAND memory 20 by designation of the same logical address. In this case, the translation information of the initial state is in a state where the certain logical address and the first physical address are correlated with each other. However, after the second data is written, the translation information comes into a state where the certain logical address and the second physical address are correlated with each other. In this way, in the translation information, the first physical address has been made not to be correlated with a logical address any more. In other words, invalidation means to make a state where a physical address included in the translation information is not correlated with a logical address. The free block information contains the block numbers of blocks containing no valid data. The free block information is formed such that the block numbers of free blocks are shown in the form of a list, for example.

The RAM 30 stores management information. At the startup of the memory system 1, the latest management information readable from the NAND memory 20 is stored in the RAM 30. The management information in the RAM 30 is updated by the memory controller 10, when a process of user data writing, erasing, or garbage collection is performed to the NAND memory 20. The management information thus updated is stored into the NAND memory 20 with arbitrary timing. In the first embodiment, the management information contains the translation information and the free block information. Further, the RAM 30 is used by the memory controller 10 as a buffer for transferring data between the host 2 and the NAND memory 20.

The memory controller 10 includes CPUs 11a to 11c, a host I/F 12, a RAM controller 13, and a NAND controller 14. The CPUs 11a to 11c, the host I/F 12, the RAM controller 13, and the NAND controller 14 are connected to each other via a bus 15. The memory controller 10 corresponds to a controller circuit or a memory control device.

The host I/F 12 executes control on the communication path 3. Further, the host I/F 12 receives a request from the host 2. Further, the host I/F 12 executes transfer of data between the host 2 and the RAM 30.

The RAM controller 13 is a controller for the memory controller 10 to access the RAM 30.

The NAND controller 14 transmits a request received from each of the CPU 11a and the CPU 11b to the NAND memory 20. Further, the NAND controller 14 executes transfer of data between the RAM 30 and the NAND memory 20. The NAND controller 14 corresponds to a memory control circuit.

The CPU 11a conducts overall control on the memory controller 10 by executing a firmware program. As part of the control, in response to a request received by the host I/F 12 from the host 2, the CPU 11a generates a command for the NAND memory 20, and transmits the command to the NAND controller 14. Further, after execution of a request is completed, the CPU 11a transmits, to the host 2 via the host I/F 12, a response indicating that execution of the request has been completed.

The CPU 11b conducts control on the memory controller 10 about the garbage collection process by executing a firmware program. In response to the garbage collection process to the memory system 1, the CPU 11b generates a command for the NAND memory 20, and transmits the command to the NAND controller 14. The garbage collection process is a process for generating one or more free blocks. Each free block is a block in a state containing none of any valid data, which is, in other words, a block in a state filled with invalid data. For example, the garbage collection is a process of collecting valid data from one or more blocks with data written therein, and moving the valid data thus collected to the other blocks. When this process is performed to collect data of areas being used and move the data into another block, a free block is generated.

The CPU 11c conducts control on the memory controller 10 about a writing permission speed by executing a firmware program. Upon receiving a write request from the host 2, the CPU 11c controls a waiting time until to return a response to the host after completion of a data writing process corresponding to the write request. Specifically, upon receiving a write request from the host 2, the CPU 11c compares an erasable capacity in the NAND memory 20 with a target value, and, on the basis of this comparison result, performs feedback control on the waiting time until to return a response to the host after completion of the data writing process. The feedback control includes Proportional-Integral-Derivative (PID) control. For example, the CPU 11c determines the waiting time, on the basis of the erasable capacity, a variation in erasable capacity, and an integration amount of erasable capacity. Here, the calculated waiting time may be controlled in proportion to the write size of a data transfer request from the host 2. For example, this is achieved by adding the calculated waiting time, for every write unit, such as 4 KiB. Completion time of the data writing process can be defined by the completion time of data transfer to the RAM 30. As described above, the RAM 30 is used as the buffer for transferring data between the host 2 and the NAND memory 20.

When the current erasable capacity has become higher than the target value, the CPU 11c reduces the waiting time; when the current erasable capacity has become lower than the target value, the CPU 11c increases the waiting time. The current erasable capacity may be obtained by counting the number of free blocks registered in the free block information, which corresponds to the total number of free blocks. Further, the current erasable capacity may be the total number of free blocks, or may be the total number of pages included in free blocks. The target value corresponds to an erasable capacity that allows a garbage collection process to be efficiently performed, without using up all the physical blocks in the NAND memory 20. For example, the target value is obtained by calculation on the assumption of the average use situation in practice of the memory system 1.

Here, the CPU 11c calculates the waiting time, but may calculate the writing permission speed, instead. In the case of a data writing process according to a write request from the host 2, as the data size is constant, the process is completed in a constant time (writing time). Accordingly, the writing permission speed can be calculated by using a constant data size, a constant writing time, and the waiting time calculated by the CPU 11c. Reducing the waiting time corresponds to increasing the writing permission speed; increasing the waiting time corresponds to reducing the writing permission speed. As described above, in the first embodiment, as the waiting time is determined for every time a request from the host 2 is received, the writing permission speed can be controlled more finely. Here, the data size of writing is arbitrary.

When the data writing process ends, the CPU 11a waits for an informed waiting time, and then returns a response to the host 2 after a lapse of the waiting time. During the waiting time, there is no request received from the host 2, and thus the CPU 11a does not transmit any request to the NAND controller 14. As a result, during the waiting time, the CPU 11b transmits a request about the garbage collection process to the NAND controller 14, and the NAND controller 14 executes the garbage collection process.

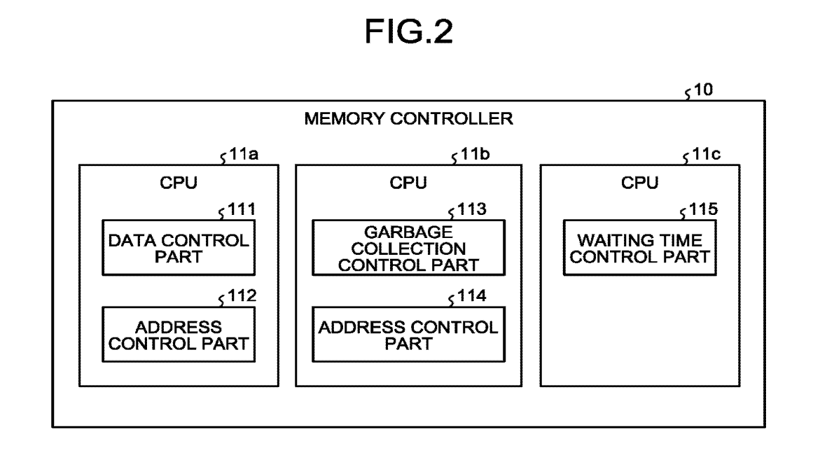

FIG. 2 is a diagram for explaining functional parts achieved by CPUs on the basis of firmware. Here, an explanation will be given of processing parts associated with this embodiment. The CPU 11a includes a data control part 111 and an address control part 112. In response to an access request from the host 2, the data control part 111 executes transfer of user data between the host 2, which is the transmission source of this access request, and the NAND memory 20. At this time, the data control part 111 receives, from the address control part 112, the translation information between address information contained in the access request and physical data addresses on the NAND memory 20, and executes the transfer of user data. Further, upon completion of a process instructed by the access request, the data control part 111 transmits a response to the host 2. In this embodiment, in a case where the access request is a write request, after the data writing process, the data control part 111 waits for a waiting time determined by a waiting time control part 115 in the CPU 11c, and then transmits a response to the host 2. The address control part 112 translates the address information contained in the access request into a physical data address on the NAND memory 20, and sends the translation result to the data control part 111. Further, the address control part 112 updates the translation information.

The CPU 11b includes a garbage collection control part 113 and an address control part 114. The garbage collection control part 113 selects user data to be moved from a block, which is treated as an object of a garbage collection process, and controls execution of the garbage collection process to move the user data thus selected to a movement destination block. The address control part 114 performs updating of the management information that needs to be changed due to the garbage collection process. This updating of the management information includes a process of invalidating user data stored in a block treated as an object of the garbage collection process; a process of registering, into the translation information, a new translation result between the logical address of the user data moved by the garbage collection process and a physical address; and a process of registering, into the free block information, a block in which all the data has become invalid data by the garbage collection process.

The CPU 11c includes a waiting time control part 115. Upon receiving a write request from the host 2, the waiting time control part 115 determines a waiting time, on the basis of an erasable capacity, or on the basis of an erasable capacity and a variation in erasable capacity or an integration amount of erasable capacity, and informs the waiting time to the CPU 11a. As described above, the erasable capacity may be obtained from the number of free blocks registered in the free block information (or the product of multiplying the number of free blocks by a storage capacity per block). Consequently, the writing permission speed from the host 2 is controlled in the CPU 11a.

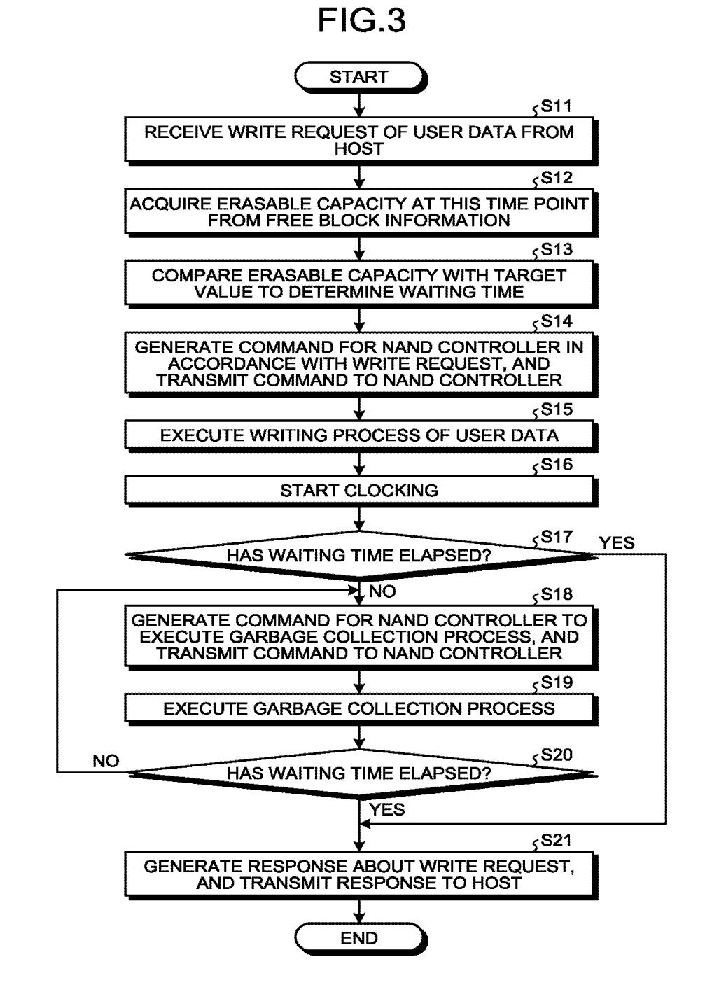

Next, an explanation will be given of a method of controlling the memory system 1. FIG. 3 is a flowchart illustrating an example of a control method of the memory system 1 according to the first embodiment. First, the host I/F 12 of the memory system 1 receives a write request of user data from the host 2 (step S11). The CPU 11c acquires an erasable capacity at this time point from the free block information (step S12), and compares this erasable capacity with a target value to determine a waiting time (step S13). For example, when the erasable capacity has become higher than the target value, the CPU 11c applies a decrease to the predetermined waiting time. When the erasable capacity has become lower than the target value, the CPU 11c applies an increase to the predetermined waiting time. When the erasable capacity is equal to the target value, the CPU 11c uses the predetermined waiting time as it is. The CPU 11c informs the waiting time thus determined to the CPU 11a.

Upon receiving the waiting time, the CPU 11a generates a command for the NAND controller 14 to write the user data in accordance with the write request, and transmits the command to the NAND controller 14 (step S14).

The NAND controller 14 executes a writing process of the user data in accordance with the command (step S15). After the writing process of the user data ends, the CPU 11a starts clocking (step S16), and determines whether the waiting time has elapsed (step S17).

While the CPU 11a is in the waiting state, the CPU 11b can transmit a command about a garbage collection process to the NAND controller 14. Specifically, when the waiting time has not yet elapsed (No at step S17), the CPU 11b generates a command for the NAND controller 14 to execute a garbage collection process, and transmits the command to the NAND controller 14 (step S18). Here, the CPU 11b generates a command for the NAND controller 14 to write valid user data in a movement source block into a movement destination block, and transmits the command to the NAND controller 14. Further, the CPU 11b makes a change in the translation information accompanying this user data movement, and registers the movement source block into the free block information if the movement source block has come into a state containing no valid user data. The NAND controller 14 executes the garbage collection process in accordance with the command (step S19).

Thereafter, the CPU 11a determines whether the waiting time has elapsed (step S20). When the waiting time has not yet elapsed (No at step S20), the process sequence returns to step S18. Further, when the waiting time has elapsed in step S17 or step S20 (Yes at step S17 or step S20), the CPU 11a generates a response to the write request, and transmits the response to the host 2 via the host I/F 12 (step S21). As a result, the process sequence ends.

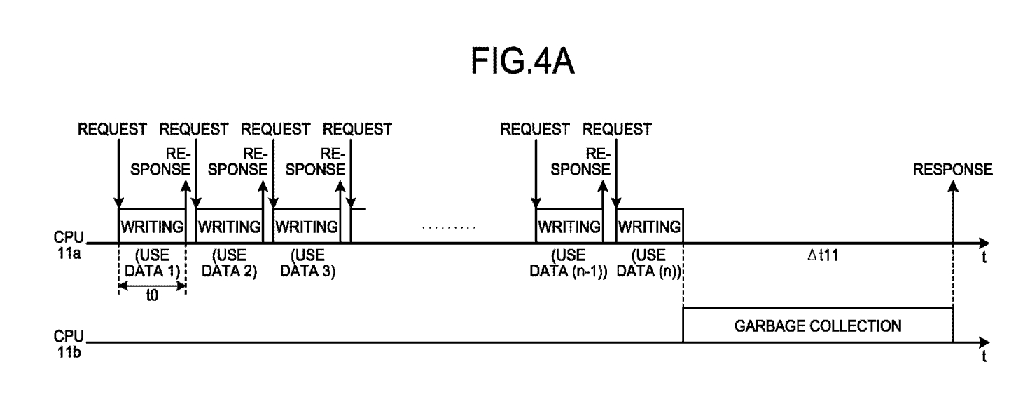

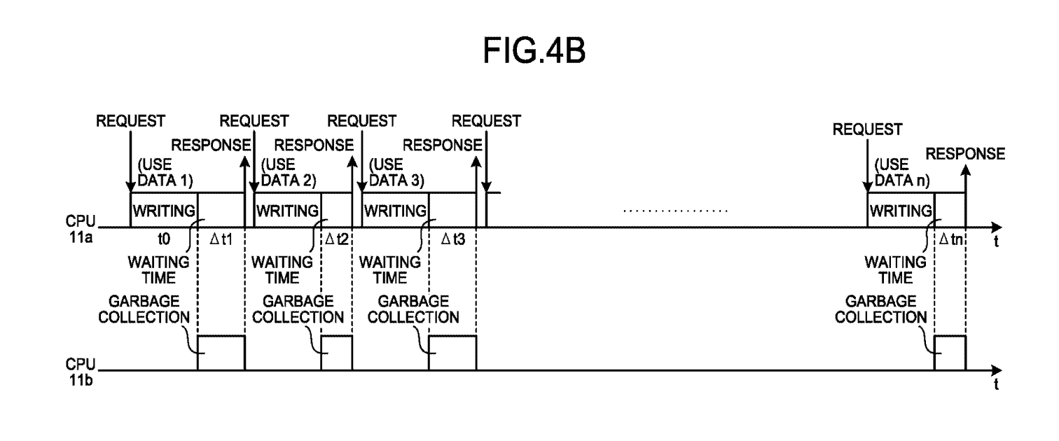

Next, an explanation will be given of an effect of this embodiment in comparison with a comparative example. FIGS. 4A and 4B are diagrams each schematically illustrating a manner of a writing process and a garbage collection process. FIG. 4A illustrates a process manner according to the comparative example. FIG. 4B illustrates a process manner according to the first embodiment. In FIGS. 4A and 4B, the horizontal axis indicates time.

In the comparative example, the writing ratio (writing permission capacity) between the writing process of data from the host and the garbage collection process is calculated in advance, to perform writing according to a plan. For example, when writing of user data with a certain size is to be performed, the user data is divided into parts each with a predetermined size in a memory system, and write requests are issued from the host for the respective parts of the user data. In this case, as illustrated in FIG. 4A, in response to each write request thus sent, the CPU 11a writes the corresponding divisional user data into the NAND memory, and returns a response to the host, upon completion of this writing. The CPU 11a repeats the above processes. Thereafter, when the amount of user data thus written reaches a predetermined writing permission capacity, the CPU 11b executes the garbage collection process. Then, when the garbage collection process ends, the CPU 11a returns a response about the write request to the host.

Here, for divisional user data from 1 to (n−1) (n is an integer of 2 or more), upon completion of the data writing process, the CPU 11a returns a response, and executes the next data writing process, without interposing a waiting time. However, for divisional user data “n”, as the garbage collection process is performed after the data writing process, the CPU 11a returns a response by interposing a time of Δt11. Where the writing time is denoted by t0, the latency for writing of the user data 1 to (n−1) is almost t0, but the latency for writing of the user data “n” becomes t0+Δt11. Thus, a variation of Δt11 is generated in the latency. Further, the latency ends up becoming very large when the garbage collection process is performed.

On the other hand, in the first embodiment, as illustrated in FIG. 4B, upon receiving a write request, the CPU 11c determine a waiting time, and performs feedback control on the writing process by using the waiting time thus determined. The determination of the waiting time is performed on the basis of the difference between an erasable capacity and a target value, or on the basis of this difference and a variation in erasable capacity or an integration amount of erasable capacity. Then, the CPU 11a transmits a command to the NAND controller 14 to write divisional user data into the NAND memory 20 in response to a write request to be received, and then waits for the determined waiting time, upon completion of the writing. The write unit used here is a controllable minimum unit. The CPU 11b transmits a command to the NAND controller 14 to execute a garbage collection process by using this waiting time, so that the garbage collection process is executed. Then, upon a lapse of the waiting time, the CPU 11a returns a response to the host 2. The CPUs 11a to 11c repeatedly execute these processes. Here, the waiting time determined for each process varies depending on an erasable capacity and its variation, at the corresponding time point.

In FIG. 4B, the waiting times for user data 1, 2, 3, . . . , and “n” are denoted by Δt1, Δt2, Δt3, . . . , and Δtn, respectively. For each of the user data 1 to “n”, the time necessary for the writing process is t0 that is constant. As a result, the latencies for writing the user data 1, 2, 3, . . . , and “n” are t0+Δt1, t0+Δt2, t0+Δt3, . . . , and t0+Δtn, respectively. Further, the sum of the waiting times Δt1 to Δtn for the respective writing processes is almost equal to the time t11 of the garbage collection process of FIG. 4A.

In the comparative example, the garbage collection process is performed in accordance with the determined writing ratio between the data writing process and the garbage collection process, and thus the latency becomes larger for a write request issued when the garbage collection process is to be performed. On the other hand, in the first embodiment, a waiting time is provided after each data writing process, and a garbage collection process is performed in this waiting time. Specifically, the comparative example performs the garbage collection process at one time, while the first embodiment performs the garbage collection processes separately at a plurality of times. Consequently, in the first embodiment, as compared with the comparative example, the garbage collection processes are dispersed, so that the maximum value of the latency can be smaller than that of the comparative example. Further, the first embodiment can suppress variations in latency as compared with the comparative example.

Here, in FIGS. 4A and 4B, an explanation has been given of the user data writing process; however, a data transfer time may be used in place of the writing process. Further, in the above description, an explanation has been given of a case where a waiting time is provided after each writing process; however, a waiting time may be provided before each writing process.

In the first embodiment, when a write request is received, a feedback control is performed on the writing permission speed to be used for when a write request is received from the host 2, on the basis of an erasable capacity, or on the basis of the erasable capacity and a variation in erasable capacity or an integration amount of erasable capacity. Specifically, the waiting time is provided after each data writing process, and is used to execute the garbage collection process. Consequently, an effect is obtained that can make smaller the maximum value of the writing latency, as compared with the comparative example. Further, an effect is obtained that can suppress variations in latency for the respective write requests.

### Second Embodiment

In a memory system, there is a case where a plurality of physical blocks (memory cell arrays) each treated as the minimum erase unit of a NAND memory are put together to construct a virtual block called “logical block”, and the logical block thus constructed is used as a management unit for erasing, writing, and reading. Further, when data is written into a NAND memory, writing is performed in order from the head page of the logical block, in units each called “frame” that is composed of a data part and a correction code. In this case, where all of the pages in the frame are formed of pages corresponding to respective physical blocks constituting the logical block, it is possible to achieve parallelization (acceleration) of writing.

The frame is classified into a fixed-length frame in which the data part has a fixed length, and a variable-length frame in which the data part has a variable length. The fixed-length frame has a size the same as that of a logical page. For writing data into the logical block, a combined method has been proposed that basically performs writing by the size of a fixed-length frame, but performs writing by a variable-length frame when the data size does not reach the size of the fixed-length frame.

Incidentally, in a memory system, before the power-off, management information, such as translation information, stored in a RAM is saved into a NAND memory, and, at the startup, the management information saved in the NAND memory is restored. Not only in a case where the power-off was performed by proper procedures, but also in a case where the power-off was improperly performed, the memory system is required to return the management information into a state with consistency, and to restore a state that enables reading of the latest data as new as possible.

In a case where the management information is written into the NAND memory by a variable-length frame, it takes a long time to perform a process for identifying frame into which the management information has been written at the startup of the memory system. Particularly, when the power-off was improperly performed, there may be a page on which writing has been done halfway, or the like, and thus it takes a long time to restore the management information.

In consideration of the above, in the second embodiment, an explanation will be given of a memory system, a memory controller, and a method of controlling memory system, which can identify the latest management information with consistency at the startup of the memory system, in a case where data in a frame is written in parallel into physical blocks constituting a NAND memory and where this writing can be performed to the NAND memory by a variable-length frame.

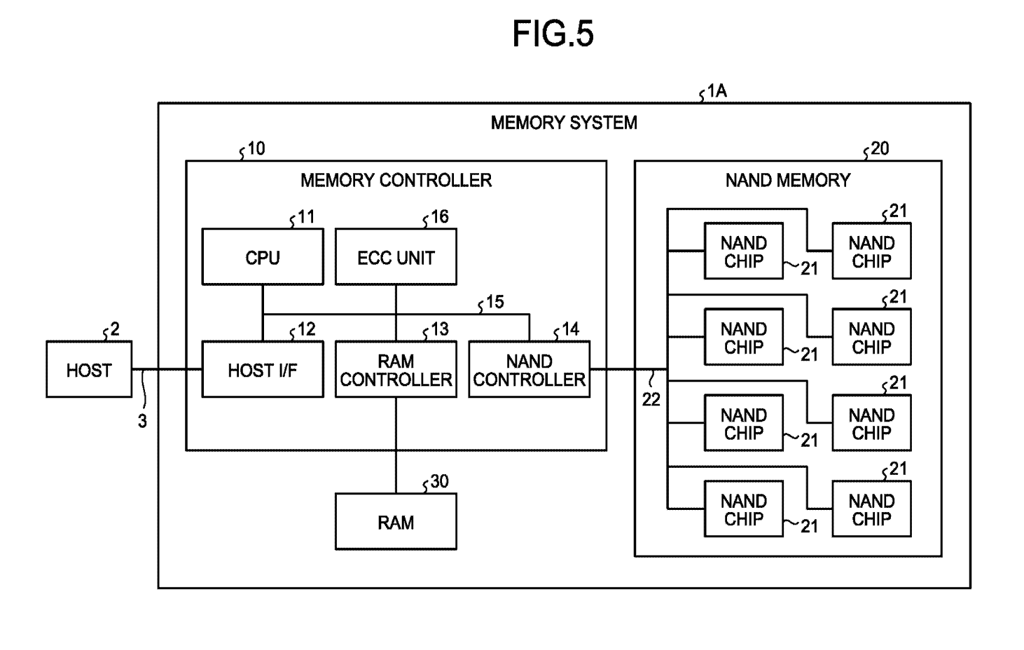

FIG. 5 is a block diagram illustrating a configuration example of a memory system according to the second embodiment. The memory system 1A includes a memory controller 10, a NAND memory 20, and a RAM 30.

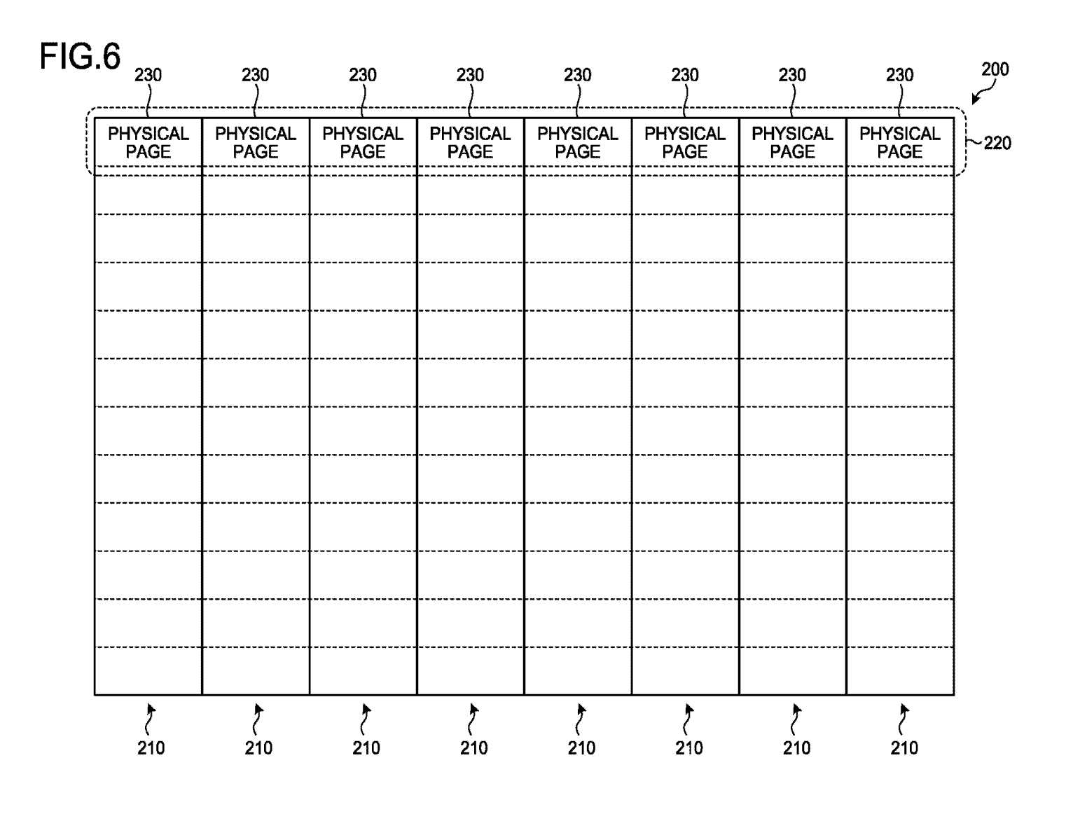

The NAND memory 20 is composed of a plurality of NAND chips 21. Each NAND chip 21 is configured such that a plurality of physical blocks are arrayed, each of which is the data erase unit. Here, physical blocks are collected one by one from different NAND chips 21 to constitute a logical block, which is a virtual block. FIG. 6 is a diagram illustrating a configuration example of the logical block. Here, one logical block 200 is composed of eight physical blocks 210. The respective physical blocks 210 belong to different NAND chips 21. Where one logical block 200 is composed of eight physical blocks 210, one logical page 220 is composed of eight physical pages 230. Here, the respective NAND chips 21 are connected to the memory controller 10 through their own signal lines 22, and thus the respective NAND chips 21 can be accessed independently of each other.

As described in the first embodiment, the NAND memory 20 stores user data and management information. The user data and the management information are written in the logical block. An explanation will be given of a way of storing data into the logical block. Here, the data to be stored is exemplified by the management information.

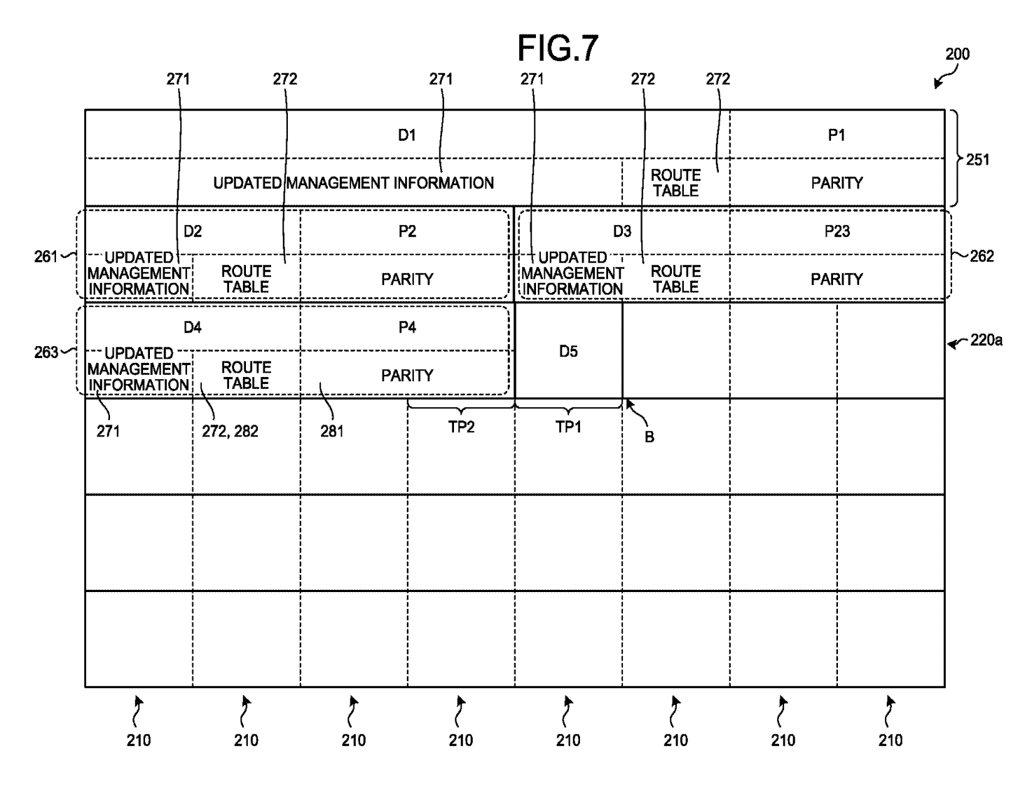

FIG. 7 is a diagram schematically illustrating data to be stored in the logical block. As described above, it is assumed that one logical block 200 is composed of eight physical blocks 210, and one logical page is composed of eight physical pages. Further, here, it is assumed that the parity (correction code) has a size corresponding to two physical pages. In the logical block 200, it is possible to write a fixed-length frame 251 having a size corresponding to one logical page (i.e., eight physical pages) and variable-length frames 261 to 263 each having a size smaller than that of one logical page (i.e., a size corresponding to seven physical pages or less). The fixed-length frame 251 includes a data part D1 corresponding to six physical pages and a parity P1 corresponding to two physical pages. The variable-length frames 261 to 263 include data parts D2, D3, and D4 each corresponding to seven physical pages or less and parities P2, P23, and P4 each corresponding to two physical pages.

Here, an explanation will be given of the parities in the variable-length frames. As illustrated in FIG. 7, the parity P1 in the fixed-length frame 251 is a parity generated with respect to the data part D1 corresponding to six physical pages. On the other hand, the variable-length frames 261 to 263 are variable in frame length. For example, the variable-length frame stored from the head of a logical page includes the data part D2 and the parity P2. The parity P2 is a parity generated with respect to the data part D2. The variable-length frame 262 stored next to the variable-length frame 261 includes the data part D3 and the parity P23. The parity P23 is not a parity generated with respect to the data part D3, but a parity generated with respect to the data of from the head of a logical page, which stores the variable-length frame 262, to a position immediately before the parity P23, i.e., with respect to the data part D2, the parity P2, and the data part D3.

Each of the data parts D1 to D4 in the fixed-length frame 251 and the variable-length frames 261 to 263 includes updated management information 271 and a route table 272 indicating the storage position of management information. The updated management information 271 is not the all data of the management information, but partial data of the management information. For example, the updated management information 271 includes updated contents in the management information.

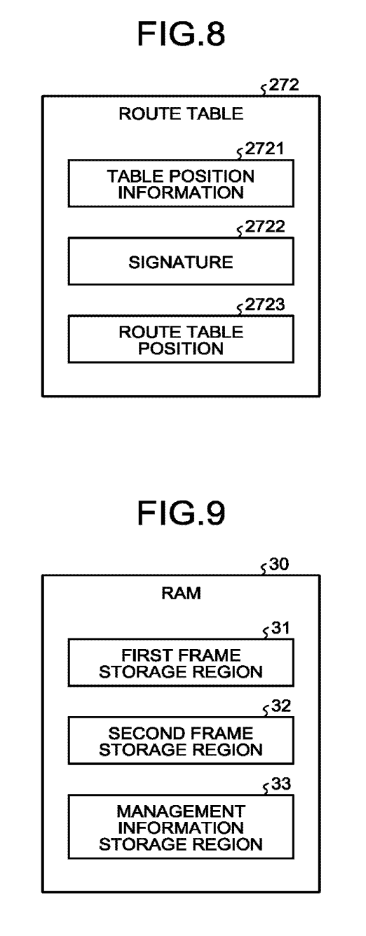

FIG. 8 is a diagram illustrating a configuration example of the route table. The route table 272 includes table position information 2721 indicating the storage position of the management information, which is to be used in the memory system 1A, on the NAND memory 20, a signature 2722 signifying the route table 272, and a route table position 2723 indicating the storage position of the route table 272 on the NAND memory 20. The table position information 2721 includes the storage position of the updated management information 271 included in each of the fixed-length frame 251 and the variable-length frames 261 to 263, and additionally includes the storage position on the NAND memory 20 about the other partial data of the management information that was not updated when the updated management information was stored this time. The signature 2722 is used to confirm whether each of the variable-length frames 261 to 263 has been correctly restored, in a restoring process described later. For example, the signature 2722 is formed of a character string signifying a route table. Further, the route table position 2723 is used to confirm whether the route table 272 is stored at the position corresponding to this route table position 2723, and to confirm whether each of the variable-length frames 261 to 263 has been correctly restored, in the restoring process described later.

Here, in the configuration described above, the plurality of NAND chips 21 are connected to the memory controller 10 through their own independent signal lines 22 so that a parallel process can be performed. Other than this, a configuration may be adopted in which each NAND chip 21 is provided with a plurality of planes so that a parallel process can be performed. The planes provided in each NAND chip 21 include peripheral circuits (such as a row decoder, column decoder, page buffer, and data cache) independent of each other, and can simultaneously perform erasing/writing/reading.

The RAM 30 has a function as described in the first embodiment, and further stores information for restoring management information at the startup of the memory system 1A, in the second embodiment. FIG. 9 is a diagram schematically illustrating a configuration example of the RAM according to the second embodiment. The RAM 30 includes a first frame storage region 31, a second frame storage region 32, and a management information storage region 33.

The first frame storage region 31 stores a restoring object frame including updated management information, which was stored at the power-off of the last time, and has been read from the NAND memory 20 at the startup. The second frame storage region 32 stores a copy of the restoring object frame stored in the first frame storage region 31. In an error correction process described later, the memory controller 10 (ECC unit 16) performs the error correction process to the restoring object frame in the second frame storage region 32. Hereinafter, where the restoring object frame stored in the first frame storage region 31 and the restoring object frame stored in the second frame storage region 32 are distinguished from each other, the restoring object frame stored in the first frame storage region 31 will be referred to as “parent restoring object frame”, and the restoring object frame stored in the second frame storage region 32 will be referred to as “daughter restoring object frame”. When the daughter restoring object frame in the second frame storage region 32 is normally read, or the daughter restoring object frame is successfully subjected to error correction, the management information storage region 33 comes to store management information, which has been read in accordance with the route table 272 of the daughter restoring object frame.

Here, the first frame storage region 31 and the second frame storage region 32 may be provided in one RAM 30, or the first frame storage region 31 and the second frame storage region 32 may be formed of a plurality of different RAMs 30 (chips).

The memory controller 10 includes a CPU 11, a host I/F 12, an RAM controller 13, a NAND controller 14, and an ECC unit 16. The CPU 11, the host I/F 12, the RAM controller 13, the NAND controller 14, and the ECC unit 16 are connected to each other via a bus 15.

The CPU 11 conducts overall control on the memory controller 10 by executing a firmware program. For example, in response to a request (command) received by the host I/F 12 from the host 2, the CPU 11 generates a command for the NAND memory 20, and transmits the command to the NAND controller 14.

The ECC unit 16 executes an error correction encoding process to data to be written into the NAND memory 20, and thereby generates a parity. The ECC unit 16 outputs codewords including the data and the parity to the NAND controller 14. Further, the ECC unit 16 executes an error correction decoding process by using codewords read from the NAND memory 20, and transfers decoded data to the RAM 30. As the error correction ability of the ECC unit 16 has an upper limit, error correction will fail when bit errors exceeding this upper limit have been generated.

Further, in the second embodiment, at the startup of the memory system 1A, the CPU 11 reads management information from a logical block in the NAND memory 20, and restores the management information. At this time, the CPU 11 identifies the last-write page in the logical block, and reads a restoring object frame of from the head of the logical page, which includes the last-write page, to the last-write page. The CPU 11 reads the restoring object frame from the NAND memory 20 into the first frame storage region 31 of the RAM 3. Consequently, the first frame storage region 31 has come to store a parent restoring object frame. Further, the CPU 11 copies the parent restoring object frame stored in the first frame storage region 31 into the second frame storage region 32 of the RAM 30. Consequently, the second frame storage region 32 has come to store a daughter restoring object frame.

The ECC unit 16 performs a correction process by using the parity to the daughter restoring object frame copied in the second frame storage region 32, and thereby generates a restored frame.

The CPU 11 reads a route table 272 from the restored frame, and uses the contents of the route table 272 to check whether the restored frame is correct. When the restored frame is correct, the CPU 11 restores the management information in the management information storage region 33 of the RAM 30, in accordance with the contents of the route table 272. On the other hand, when the restored frame is not correct, the CPU 11 discards the restored frame in the second frame storage region 32, and copies the parent restoring object frame in the first frame storage region 31 into the second frame storage region 32. The CPU 11 moves the position of the end page of the daughter restoring object frame forward by a predetermined length from the position assumed at the last time. Then, the CPU 11 and the ECC unit 16 performs the processes described above, and the CPU 11 determines whether a restored frame has been correctly generated, for the daughter restoring object frame with the end page thus changed.

Here, the constituent elements corresponding to those described in the first embodiment are denoted by the same reference symbols, and their description is omitted.

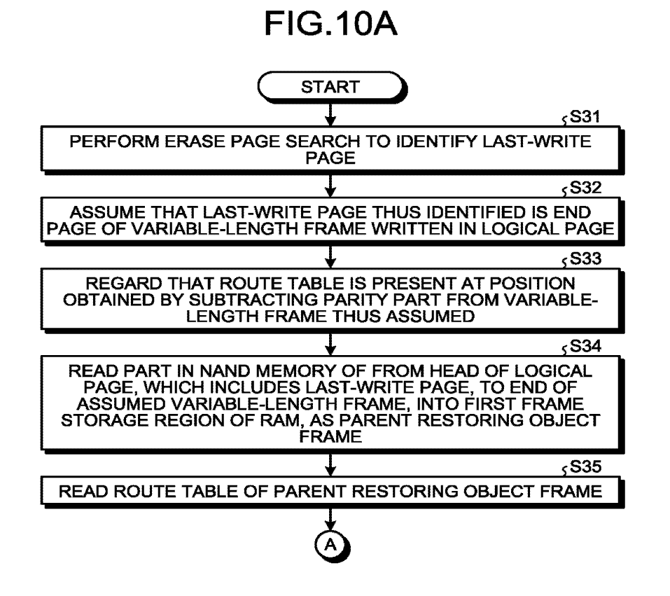

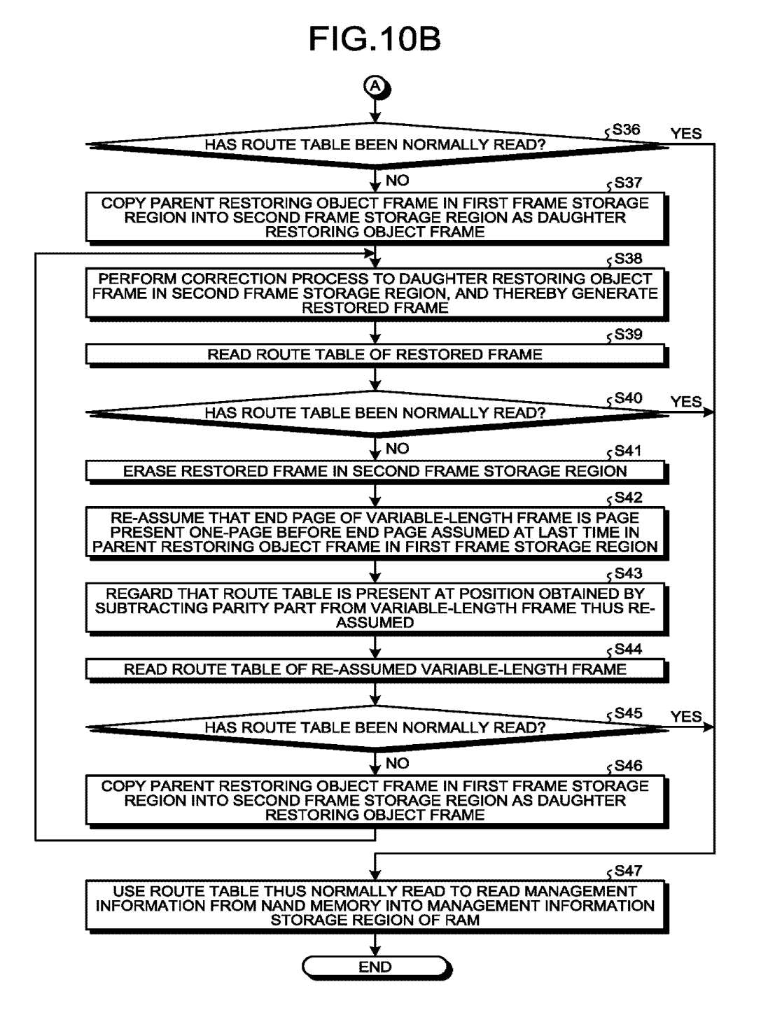

Next, an explanation will be given of a management information restoring process in detail. FIGS. 10A and 10B are flowcharts each illustrating an example of a sequence of a management information restoring process according to the second embodiment. At the power-on of the memory system 1A, the CPU 11 performs an erase page search to a logical block in the NAND memory 20, to identify the last-write page (step S31). The erase page search is a searching method that makes an inquiry whether to be an erase page, in order from the end page to the head page in a logical block; when detecting a page that is not an erase page for the first time, the method recognizes this position as the last-write page. Here, when writing is performed to the logical block, the NAND memory 20 performs the writing in the ascending order of page numbers from the head page.

The CPU 11 assumes that the last-write page thus identified is the end page of a variable-length frame written in the logical page (step S32). Then, the CPU 11 regards that a route table is present at the position obtained by subtracting a parity (correction code part) from the variable-length frame thus assumed (step S33). As described above, in this example, as the parity corresponds to two physical pages, the CPU 11 regards that the route table is present at the position obtained by subtracting a part corresponding to two physical pages from the assumed variable-length frame.

Thereafter, the CPU 11 reads the part in the NAND memory 20, of from the head of the logical page, which includes the last-write page, to the end of the assumed variable-length frame. The CPU 11 reads this part in parallel into the first frame storage region 31 of the RAM 30 as a parent restoring object frame (step S34). In other words, the CPU 11 performs this reading, for a plurality of physical pages constituting the logical page, independently of and in parallel with each other.

Then, the CPU 11 reads the route table 272 of the parent restoring object frame thus read (step S35), and determines whether the route table 272 has been normally read (step S36). In other words, after reading the route table 272 assumed in step S33, when the CPU 11 can normally read the signature 2722 in the route table 272, and find that the route table 272 is stored at the position indicated by the route table position 2723, the CPU 11 determines that the route table 272 has been normally read. On the other hand, when the CPU 11 cannot normally read the signature 2722 in the route table 272, or cannot find that the route table 272 is stored at the position indicated by the route table position 2723, the CPU 11 determines that the route table 272 has not been normally read.

When the route table 272 has not been normally read (No at step S36), the CPU 11 copies the parent restoring object frame in the first frame storage region 31 into the second frame storage region 32 as a daughter restoring object frame (step S37). Then, the ECC unit 16 performs a correction process to the daughter restoring object frame in the second frame storage region 32, and thereby generates a restored frame (step S38). Specifically, the ECC unit 16 considers data corresponding to two pages from the assumed end as a parity, and performs the correction process by using this parity. Consequently, the restoring object frame is subjected to correction and is turned into the restored frame.

Thereafter, the CPU 11 reads the route table 272 of the restored frame (step S39), and determines whether the route table 272 has been normally read (step S40). The determination made here is substantially the same as that described in step S36. As a result of the determination, when the route table 272 has not been normally read (No at step S40), the CPU 11 erases the restored frame stored in the second frame storage region 32 (step S41).

The CPU 11 regards that there is an error in assumption about the end page of the variable-length frame in step S32, and re-assumes that the end page of the variable-length frame is the page present one-page before the end page assumed at the last time in the parent restoring object frame stored in the first frame storage region 31 (step S42). Then, the CPU 11 regards that a route table is present at the position obtained by subtracting a parity part from the variable-length frame thus re-assumed in the first frame storage region 31 (step S43).

Thereafter, the CPU 11 reads the route table 272 of the re-assumed variable-length frame in the first frame storage region 31 (step S44), and determines whether the route table 272 has been normally read (step S45). The determination made here is substantially the same as that described in step S36. As a result of the determination, when the route table 272 has not been normally read (No at step S45), the CPU 11 copies the part of the parent restoring object frame stored in the first frame storage region 31, of from its head to the end of the variable-length frame assumed in step S42. The CPU 11 copies this part into the second frame storage region 32 as a daughter restoring object frame (step S46). Thereafter, the process sequence shifts to step S38.

On the other hand, when the route table 272 has been normally read in step S36, step S40, or step S45 (Yes at step S36, S40, or S45), the CPU 11 uses the route table 272 thus normally read to read the management information from the NAND memory 20 into the management information storage region 33 of the RAM 30 (step S47). As a result, the process sequence ends.

Here, in the above description, the parity size corresponds to two physical page; however, the embodiment is not limited to this. For example, the parity size may be set to a positive integral multiple of the physical page. In this case, when the end page of the variable-length frame is to be re-assumed in step S42, this end page may be the page present one-page before the end page assumed at the last time in the read frame in the first frame storage region 31.

Further, the data write unit (page) into the NAND memory 20 and the data minimum management unit in the NAND memory 20 may be set the same as each other, or may be set different from each other. For example, the data write unit into the NAND memory 20 may be set to a positive integral multiple of the data minimum management unit in the NAND memory 20. With this setting, the parity size can be set to a positive integer fraction of the physical page. In this case, when the end page of the variable-length frame is to be re-assumed in step S42, this end page may be the page present ahead, by a positive integer fraction of the physical page, of the end page assumed at the last time in the read frame in the first frame storage region 31.

An explanation will be given of a specific example of the management information restoring process, with reference to FIG. 7. In FIG. 7, it is assumed that the power-off was improperly generated in the middle of writing data D5. Accordingly, it is assumed that no parity about the data D5 has been written into the logical block 200.

When the memory system 1A starts up from this state, the boundary B between the last-write page and the erase page is acquired by the erase page search. The CPU 11 assumes that the part obtained by tracing back from this boundary B by one physical page is the end page TP1 of a variable-length frame. Thus, the CPU 11 regards that the route table 272 is present at the position (page 281) obtained by subtracting a parity corresponding to two physical pages from this end page TP1.

Here, the processes of steps S35 to S40 of FIGS. 10A and 10B are executed. However, the page assumed as the end page TP1 by the erase page search actually does not store the parity, but stores the data D5 for which writing has been done halfway. Thus, the route table 272 cannot be successfully read, and even a correction process using a parity cannot achieve successful reading of the route table 272. Here, the correction process is performed to the daughter restoring object frame formed of a copy into the second frame storage region 32.

As the route table 272 has not been successfully read, the restored frame in the second frame storage region 32 is erased, and the page present one-page before the end page TP1 assumed at the last time is re-assumed as a new end page TP2. Further, the CPU 11 regards that the route table 272 is present at the position (page 282) obtained by subtracting a parity corresponding to two physical pages from this end page TP2.

Here, the processes of steps S44 to S46 and S38 to S39 are executed. As the re-assumed end page TP2 agrees with the end page of the variable-length frame 263, the route table 272 can be successfully read. Accordingly, the management information is restored by using the variable-length frame 263, which is from the head of the logical page 220a to the re-assumed end page TP2.

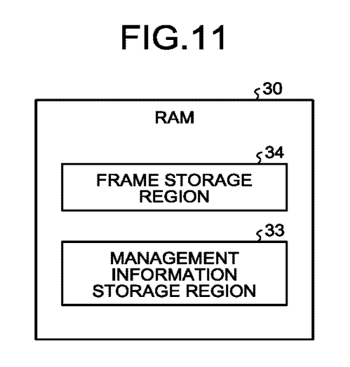

Next, an explanation will be given of an effect of the first embodiment in comparison with a management information restoring process according to a comparative example. FIG. 11 is a diagram schematically illustrating a configuration example of a RAM according to a comparative example. In the comparative example, the RAM 30 includes a frame storage region 34 and a management information storage region 33. The frame storage region 34 stores a restoring object frame including management information, which was saved at the power-off of the last time, and has been read from the NAND memory 20 at the startup. In the comparative example, an error correction process is performed to this restoring object frame stored in the frame storage region 34. Here, the constituent elements corresponding to those described with reference to FIG. 8 are denoted by the same reference symbols, and their description will be omitted.

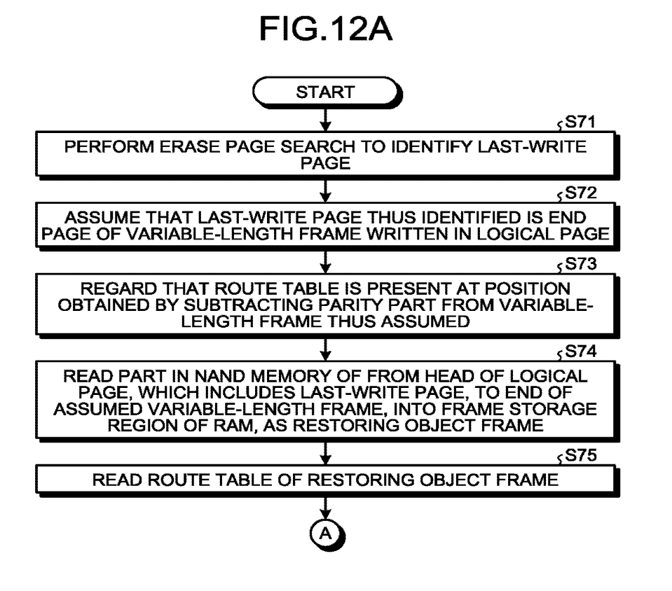

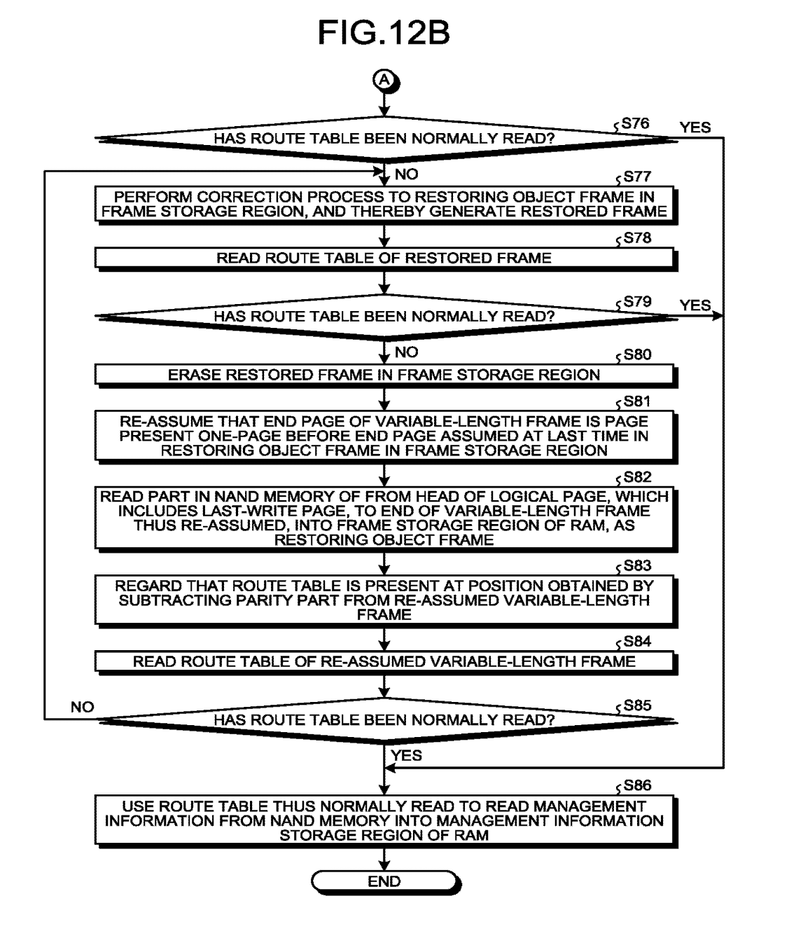

FIGS. 12A and 12B are flowcharts each illustrating an example of a sequence of a management information restoring process according to the comparative example. As in steps S31 to S33 of the first embodiment, at the power-on of the memory system 1A, the CPU 11 performs an erase page search to a logical block in the NAND memory 20, to identify the last-write page, and assumes that the last-write page thus identified is the end page of a variable-length frame. Then, the CPU 11 regards that the route table 272 is present at the position obtained by subtracting a parity part from the variable-length frame thus assumed (steps S71 to S73).

Then, the CPU 11 reads the part in the NAND memory 20, of from the head of the logical page, which includes the last-write page, to the end of the assumed variable-length frame. The CPU 11 reads this part in parallel into the frame storage region 34 of the RAM 30 as a restoring object frame (step S74). Further, the CPU 11 reads the route table 272 of the restoring object frame thus read (step S75), and determines whether the route table 272 has been normally read (step S76). The determination made here is substantially the same as that described in step S36 of FIG. 10B.

When the route table 272 has not been normally read (No at step S76), the ECC unit 16 performs a correction process to the restoring object frame in the frame storage region 34, and thereby generates a restored frame (step S77). Specifically, the ECC unit 16 considers data corresponding to two pages from the assumed end as a parity, and performs the correction process by using this parity. Consequently, the restoring object frame is turned into the restored frame.

Thereafter, the CPU 11 reads the route table 272 of the restored frame (step S78), and determines whether the route table 272 has been normally read (step S79). The determination made here is substantially the same as that described in step S36. As a result of the determination, when the route table 272 has not been normally read (No at step S79), the CPU 11 erases the restored frame stored in the frame storage region 34 (step S80).

Then, the CPU 11 regards that there is an error in assumption about the end page of the variable-length frame in step S72, and re-assumes that the end page of the variable-length frame is the page present one-page before the end page assumed at the last time in the restoring object frame stored in the frame storage region 34 (step S81). Thereafter, the CPU 11 reads the part in the NAND memory 20, of from the head of the logical page, which includes the last-write page, to the end of the variable-length frame thus re-assumed. The CPU 11 reads this part in parallel into the frame storage region 34 of the RAM 30 as a restoring object frame (step S82).

Then, the CPU 11 regards that the route table 272 is present at the position obtained by subtracting a parity part from the newly assumed variable-length frame in the frame storage region 34 (step S83). Thereafter, the CPU 11 reads the route table 272 of the assumed variable-length frame in the frame storage region (step S84), and determines whether the route table 272 has been normally read (step S85). The determination made here is substantially the same as that described in step S36.

As a result of the determination, when the route table 272 has not been normally read (No at step S85), the process sequence shifts to step S77, in which the part of the restoring object frame in the frame storage region 34, of from its head to the end of the variable-length frame assumed in step S81, is used as a new restoring object frame.

On the other hand, when the route table 272 has been normally read in step S76, step S79, or step S85 (Yes at step S76, S79, or S85), the route table 272 thus normally read is used to read the management information from the NAND memory 20 into the management information storage region 33 of the RAM 30 (step S86). As a result, the process sequence ends.

In the comparative example, a restoring object frame obtained as a result of the erase page search is read from the NAND memory 20 into the frame storage region 34 of the RAM 30, and a correction process is performed to the frame thus read. Accordingly, when the frame end page is incorrectly assumed, data read into the frame storage region 34 becomes a restored frame subjected to correction by an erroneous correction code. Thus, the restored frame is discarded, and the restoring object frame is read again from the NAND memory 20 into the frame storage region 34.

In the second embodiment, a restoring object frame obtained as a result of the erase page search is stored from the NAND memory 20 into the first frame storage region 31 of the RAM 30 as a parent restoring object frame. Further, the parent restoring object frame is copied into the second frame storage region 32 as a daughter restoring object frame. Then, a correction process is performed to the daughter restoring object frame. Accordingly, when the frame end page is incorrectly assumed, a restored frame in the second frame storage region 32 subjected to correction by an erroneous correction code is discarded. However, a new daughter restoring object frame is made by a copy from the first frame storage region 31 into the second frame storage region 32. Then, a correction process is performed again to the daughter restoring object frame, under re-assumed conditions. The time necessary for copying the restoring object frame stored in the first frame storage region 31 of the RAM 30 into the second frame storage region 32 is far shorter than the time necessary for reading a restoring object frame stored in the NAND memory 20 into the RAM 30. Thus, in the second embodiment, an effect is obtained that can shorten the startup time of the memory system 1A, as compared with the comparative example. Particularly, in a case where the frame end needs to be re-assumed a plurality of times, this difference in time necessary for copying becomes increasingly larger, and the effect of shortening the startup time becomes notable.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a nonvolatile memory including a plurality of blocks in which data is written from an external member, each of the blocks being an unit of erasure; and
a controller circuit that controls execution of a data writing process and a garbage collection process, the data writing process including a process of writing user data into the nonvolatile memory in accordance with a request from the external member, the garbage collection process including a process of moving valid data in at least a first block into a second block among the blocks and invalidating the valid data in the first block to be erasable, wherein,
upon receiving a data write request from the external member, the controller circuit controls a length of a waiting time to be provided before or after the data writing process within a period from receiving the write request to returning a response to the external member.

2. The memory system according to claim 1, wherein, upon receiving the write request, the controller circuit compares an erasable capacity corresponding to a capacity of free blocks in the nonvolatile memory with a target value, and performs, in accordance with a comparison result, feedback control on the waiting time, the free blocks being filled with invalid data.

3. The memory system according to claim 2, wherein, upon receiving the write request, the controller circuit determines the waiting time, on a basis of a difference between the erasable capacity and the target value, a variation in the erasable capacity, and an integration amount of the erasable capacity.

4. The memory system according to claim 2, wherein the controller circuit
determines the waiting time upon receiving the write request,
performs the data writing process,
performs the garbage collection process during the determined waiting time after completion of the data writing process, and
returns the response after a lapse of the waiting time.

5. The memory system according to claim 2, wherein the controller circuit
determines the waiting time upon receiving the write request,
performs the garbage collection process during the determined waiting time,
performs the data writing process after a lapse of the waiting time, and
returns the response after completion of the data writing process.

6. The memory system according to claim 2, wherein the controller circuit reduces the waiting time when the erasable capacity is higher than the target value, and increases the waiting time when the erasable capacity is lower than the target value.

7. The memory system according to claim 1, wherein the nonvolatile memory comprises a NAND type flash memory.

8. A memory control device comprising:
a memory control circuit that controls a nonvolatile memory, the nonvolatile memory including a plurality of blocks in which data is written from an external member, each of the blocks being an unit of erasure, and
a processor that
controls execution of a data writing process and a garbage collection process, the data writing process including a process of writing user data into the nonvolatile memory in accordance with a request from the external member, the garbage collection process including a process of moving valid data in at least a first block into a second block among the blocks and invalidating the valid data in the first block to be erasable, and
controls, upon receiving a data write request from the external member, a length of a waiting time to be provided before or after the data writing process within a period from receiving the write request to returning a response to the external member.

9. The memory control device according to claim 8, wherein, upon receiving the write request, the processor compares an erasable capacity corresponding to a capacity of free blocks in the nonvolatile memory, with a target value, and performs, in accordance with a comparison result, feedback control on the waiting time, the free blocks being filled with invalid data.

10. The memory control device according to claim 9, wherein, upon receiving the write request, the processor determines the waiting time, on a basis of a difference between the erasable capacity and the target value, a variation in the erasable capacity, and an integration amount of the erasable capacity.

11. The memory control device according to claim 9, wherein the processor
determines the waiting time upon receiving the write request,
performs the data writing process,
performs the garbage collection process during the determined waiting time after completion of the data writing process, and
returns the response after a lapse of the waiting time.

12. The memory control device according to claim 9, wherein the processor
determines the waiting time upon receiving the write request,
performs the garbage collection process during the determined waiting time,
performs the data writing process after a lapse of the waiting time, and
returns the response after completion of the data writing process.

13. The memory control device according to claim 9, wherein the processor reduces the waiting time when the erasable capacity is higher than the target value, and increases the waiting time when the erasable capacity is lower than the target value.

14. A method of controlling memory system that includes a nonvolatile memory including a plurality of blocks in which data is written, each of the blocks being an unit of erasure, the method comprising:
executing a data writing process to write user data into the nonvolatile memory in accordance with a request from an external member; and
executing a garbage collection process to move valid data in at least a first block into a second block among the blocks and to invalidate the valid data in the first block to be erasable,
wherein, the method further comprising
controlling, upon receiving a data write request from the external member, a length of a waiting time to be provided before or after the data writing process within a period from receiving the write request to returning a response to the external member.

15. The method according to claim 14, wherein the controlling of the length of the waiting time includes
comparing, upon receiving the write request, an erasable capacity corresponding to a capacity of free blocks in the nonvolatile memory, with a target value, and,
performing, in accordance with a comparison result, feedback control on the waiting time, the free blocks being filled with invalid data.

16. The method according to claim 15, wherein, in the controlling of the length of the waiting time, upon receiving the write request, the waiting time is determined on a basis of a difference between the erasable capacity and the target value, a variation in the erasable capacity, and an integration amount of the erasable capacity.

17. The method according to claim 15, comprising:
determining the waiting time upon receiving the write request;
performing the data writing process;
performing the garbage collection process during the determined waiting time after completion of the data writing process; and
returning the response after a lapse of the waiting time.

18. The method according to claim 15, comprising:
determining the waiting time upon receiving the write request;
performing the garbage collection process during the determined waiting time;
performing the data writing process after a lapse of the waiting time; and
returning the response after completion of the data writing process.

19. The method according to claim 15, wherein, in the controlling of the length of the waiting time, the waiting time is reduced when the erasable capacity is higher than the target value, and the waiting time is increased when the erasable capacity is lower than the target value.

20. The method according to claim 14, wherein the nonvolatile memory comprises a NAND type flash memory.
